(19) United States
(12) Patent Application Publication
(10) Pub. No.: US 2014/0191218 A1
(43) Pub. Date: Jul. 10, 2014

(54) X-RAY-SENSITIVE DEVICES AND SYSTEMS USING ORGANIC PN JUNCTION PHOTODIODES

(71) Applicants: Beck Radiological Innovations Inc, Catonsville, MD (US); The Johns Hopkins University, Baltimore, MD (US)

(72) Inventors: Howard E. Katz, Owings Mill, MD (US); Hoyoul Kong, Timonium, MD (US); Thomas J. Beck, Catonsville, MD (US)

(73) Assignees: Beck Radiological Innovations Inc, Catonsville, MD (US); The Johns Hopkins University, Baltimore, MD (US)

(21) Appl. No.: 14/149,561

(22) Filed: Jan. 7, 2014

Related U.S. Application Data
(60) Provisional application No. 61/749,749, filed on Jan. 7, 2013.

(51) Int. Cl. H01L 51/44

(52) U.S. Cl. CPC H01L 51/44
USPC 257/40

(57) ABSTRACT

An x-ray detector includes a first electrode, a second electrode spaced apart from the first electrode, an organic p-type semiconducting layer disposed between the first and second electrodes, and an organic n-type semiconducting layer disposed between the first and second electrodes and in contact with the organic p-type semiconducting layer to form a pn-junction layer therebetween. At least one of the organic p-type semiconducting layer or the organic n-type semiconducting layer includes an x-ray absorbing material blended therein.

### CROSS-REFERENCE OF RELATED APPLICATION

This application claims priority to U.S. Provisional Application No. 61/749,749, filed Jan. 7, 2013, the entire contents of which are hereby incorporated by reference.

This invention was made with Government support of Grant No. 0823947, awarded by the National Science Foundation. The U.S. Government has certain rights in this invention.

### BACKGROUND

1. Technical Field

The field of the currently claimed embodiments of this invention relates to X-ray sensitive devices and systems, and more particularly to X-ray sensitive devices and systems that use organic pn-junction photodiodes.

2. Discussion of Related Art

Over the past several years, solution-processed organic materials have been progressively incorporated into organic light emitting diodes (OLEDs) [1-3], organic field-effect transistors (OFETs) [4-10], organic photovoltaic cells (OPVs) [11-15], and organic photodiodes [16-18]. The advantages of solution processes such as ink jet and roll-to-roll techniques [19] are low cost for large-area applications, and compatibility with mechanically flexible and lightweight substrates [20]. Recently, research on photodiodes using many classes of organic materials as active layers has attracted considerable attention for applications such as signal processing and optical detection [21-24]. Most of these photodiodes were fabricated by vacuum deposition with p- and n-type small molecules [25-28], or by solution processing using electron donor polymers including poly(3-hexylthiophene) (P3HT) and phenyl-C61-butyric acid methyl ester (PCBM) as an electron acceptor [17, 29, 30].

Photovoltaic devices with the layer sequence PET foil/ITO/PEDOT:PSS/P3HT:PCBM (PET is (poly(ethylene terephthalate) polyester, where ITO is indium tin oxide, and PEDOT:PSS is poly(ethylenedioxythiophene:poly(styrenesulfonate) and where P3HT:PCBM are blended in 1:3 wt %, have been reported to have a forward to reverse current ratio of 5×10³ at ±2V in the dark with a forward bias current density as high as 70 mA/cm² at 2.0 V [31]. A solution processable bilayer photovoltaic device consisting of P3HT/PCBM (P3HT from chlorobenzene (CB) and PCBM from dichloromethane (DCM)) on ITO-coated glass covered with PEDOT:PSS had current density of 9.35 mA/cm² [32]. Recently, we reported solution-processed bilayer organic films using an electron-transporting blended layer (PCBM and poly(4-bromostyrene) (PBrS)) on a hole-transporting layer [33]. The blend allowed a smoother, more continuous electron-transporting film while retaining 10-50% of the mobility of neat, solution-deposited PCBM. Rectification of the bilayer was also observed. To minimize the dissolution or other modification of the bottom organic layer, we also used the relatively orthogonal solvent DCM for depositing the n-layer [33-35]. However, it has been observed that PCBM, if not blended with a polymer, would diffuse into amorphous regions of a P3HT layer with little disruption of the crystalline polymer regions even at modest temperature. [36, 37] Bilayer devices have shown lower power conversion efficiency than bulk heterojunctions, but the bilayer architecture in principle has the advantage that the separated electrons and holes can reach the corresponding electrodes with less recombination. [32, 38] Also, the processing for bilayer devices is much simpler, as there is less reliance on and sensitivity to thermal annealing conditions and phase equilibria. There thus remains a need for improved X-ray sensitive devices and systems that use organic pn-junction photodiodes.

### SUMMARY

An x-ray detector according to an embodiment of the current invention includes a first electrode, a second electrode spaced apart from the first electrode, an organic p-type semiconducting layer disposed between the first and second electrodes, and an organic n-type semiconducting layer disposed between the first and second electrodes and in contact with the organic p-type semiconducting layer to form a pn-junction layer therebetween. At least one of the organic p-type semiconducting layer or the organic n-type semiconducting layer includes an x-ray absorbing material blended therein.

An x-ray detector according to an embodiment of the current invention includes a first electrode, a second electrode spaced apart from the first electrode, an organic p-type semiconducting layer disposed between the first and second electrodes, an organic n-type semiconducting layer disposed between the first and second electrodes and in contact with the organic p-type semiconducting layer to form a pn-junction layer therebetween, and an x-ray absorbing layer disposed proximate at least one of the organic p-type semiconducting layer or the organic n-type semiconducting layer such that secondary electrons produced in the x-ray absorbing layer in response to absorbed x-rays excite at least one of the organic p-type semiconducting layer or the organic n-type semiconducting layer.

An x-ray imaging system according to an embodiment of the current invention includes an array of x-ray detector elements. At least one x-ray detector element of the array of x-ray detector elements includes a first electrode, a second electrode spaced apart from the first electrode, an organic p-type semiconducting layer disposed between the first and second electrodes, and an organic n-type semiconducting layer disposed between the first and second electrodes and in contact with the organic p-type semiconducting layer to form a pn-junction layer therebetween. At least one of the organic p-type semiconducting layer or the organic n-type semiconducting layer includes an x-ray absorbing material blended therein.

An x-ray imaging system according to an embodiment of the current invention includes an array of x-ray detector elements. At least one x-ray detector element of the array of x-ray detector elements includes a first electrode, a second electrode spaced apart from the first electrode, an organic p-type semiconducting layer disposed between the first and second electrodes, an organic n-type semiconducting layer disposed between the first and second electrodes and in contact with the organic p-type semiconducting layer to form a pn-junction layer therebetween, and an x-ray absorbing layer disposed proximate at least one of the organic p-type semiconducting layer or the organic n-type semiconducting layer such that secondary electrons produced in the x-ray absorbing layer in response to absorbed x-rays excite at least one of the organic p-type semiconducting layer or the organic n-type semiconducting layer.

A tissue-equivalent radiation detector according to an embodiment of the current invention includes a first electrode, a second electrode spaced apart from the first electrode, an organic p-type semiconducting layer disposed between the first and second electrodes, and an organic n-type semiconducting layer disposed between the first and second electrodes and in contact with the organic p-type semiconducting layer to form a pn-junction layer therebetween. The organic p-type semiconducting layer and the organic n-type semiconducting layer together have an average atomic number that is approximately 7.4 to substantially match an average atomic number of muscle tissue.

### BRIEF DESCRIPTION OF THE DRAWINGS

Further objectives and advantages will become apparent from a consideration of the description, drawings, and examples.

FIG. 1 is a schematic illustration of an x-ray detector according to an embodiment of the current invention.

FIG. 2 is a schematic illustration of an x-ray detector according to another embodiment of the current invention.

FIG. 3 is a schematic illustration of an x-ray detector according to another embodiment of the current invention.

FIG. 4 is an illustration of an x-ray imaging system according to another embodiment of the current invention.

FIG. 5 is an illustration of a portion of an x-ray imaging system according to another embodiment of the current invention.

FIG. 6 shows UV-vis spectra of the P3HT film, PCBM film, and P3HT::PCBM:PClS(9:1) bilayer film.

FIGS. 7A-7B provide (a) a schematic diagram of the photodiode device. (b) Current density-voltage characteristics of ITO/P3HT/PCBM:PClS/Al device under dark condition.

FIGS. 8A-8C provide (a) Current density-voltage characteristics of the photodiode devices with various sizes of A1 top electrodes in the dark and under illumination (Xenon lamp with a light intensity of 130 mW/cm²). The on/off characteristics (relative current increase) of the same devices at (b) −2 V (reverse) and (c) +2 V (forward) bias voltage under the same dark and illumination conditions.

FIGS. 9A79G provide current density-voltage characteristics of the photodiode device with (a) 77 nm, (b) 500 nm, and (c) 4,100 nm thickness of organic film under dark and illumination (Xenon lamp with a light intensity of 130 mW/cm²) conditions. The on/off characteristics of the same devices at (d) −2 V and (f) +2 V bias voltage. (e) and (g) is expanded graph of (d) and (f), respectively, under same dark and illumination conditions.

FIGS. 10A-10B show the on/off characteristics of the photodiode device exposed to the various light exposures (Xenon lamp with a light intensity of 112˜291 mW/cm², Halogen lamp with a light intensity of 0.013˜1.51 mW/cm², and UV lamp (λ=365 nm) with a light intensity of 0.35 mW/cm²) continuously at (a) −2 V and (b) +2 V bias voltage.

FIGS. 11A-11B show (a) Photogenerated current density as a function of illuminated light intensity (0.013˜291 mW/cm²) for the photodiode at −2 V bias voltage. (Inset: expanded graph for the points nearest the origin). (b) Logarithmic plot of photogenerated current density as a function of illuminated light intensity for the photodiode at −2 V bias voltage.

FIGS. 12A-12B show (a) Photocurrent-response spectra of ITO/P3HT/PCBM:PClS/A1 device under illumination with UV-Vis light. (b) Incident photon to current conversion efficiencies (IPCE) of ITO/P3HT/PCBM:PClS/A1 device under illumination.

FIGS. 13A-13D show (a) The image of the connected photodiode devices in parallel. (b) Current-voltage characteristics of the single or connected photodiode devices under dark and illumination (Xenon lamp with a light intensity of 130 mW/cm²) conditions. (c) The on/off characteristics of the same devices at (d) −2 V and (f) +2 V bias voltage, under the same dark and illumination conditions.

### DETAILED DESCRIPTION

Some embodiments of the current invention are discussed in detail below. In describing embodiments, specific terminology is employed for the sake of clarity. However, the invention is not intended to be limited to the specific terminology so selected. A person skilled in the relevant art will recognize that other equivalent components can be employed and other methods developed without departing from the broad concepts of the current invention. All references cited anywhere in this specification, including the Background and Detailed Description sections, are incorporated by reference as if each had been individually incorporated.

There is a wide unmet need for flexible, low-cost electronic x-ray detectors. Potential applications can include mapping of extraneous x-rays in medical settings, measuring x-ray dosages and spatial profiles for patient diagnostics and therapeutics, direct x-ray image recorders, and nondestructive materials evaluation, for example. Organic semiconductors combine the ability to tune carrier energies and absorbance maxima, blend functional additives, control atomic x-ray absorbance, and form flexible films with utility in pn junction diodes that respond to irradiation. The materials of this invention are designed so that p and n semiconductors can be deposited to form bilayers where the intended carrier transport function of each layer is maintained. Electrodes are supplied to inject the appropriate charges at the cathode and anode faces of the device. Devices according to some embodiments of this invention can operate in air when formed on flexible plastic substrates, and require minimal vacuum fabrication. In some embodiments, multiple devices can be stacked to receive electromagnetic radiation input as an ensemble, with parallel electrode connections, so currents generated in response are additive. In some embodiments, devices can operate as large monolithic photodiodes or as pixelated diode arrays integrated with x-y grid backplanes analogous to display backplanes. In some embodiments, devices can be integrated with scintillator screens, or can be made inherently x-ray sensitive by the addition of heavy element absorbers. Conversely, devices can be fabricated entirely with elements with atomic number below 18, or even 10, and compositionally tuned to have x-ray absorbance matched to biological materials of interest for applications in radiation dosimetry.

According to some embodiments of the current invention, high rectification is obtained from large area thin film devices comprising at least one hole-carrying and one electron-carrying organic layer. Each layer can be deposited from solution to coat a large area without too many short circuits. Compatible hole and electron injecting electrodes and flexible substrates can be provided. The devices are operated in reverse bias, and show dose-dependent photocurrents when exposed to visible light. X-ray sensitivity can be obtained if the visible light is generated by scintillation of an additional film or constituent on exposure to x-rays. Alternatively, the device can be inherently x-ray sensitive, and made more so by the introduction of x-ray absorbing additives. A design, according to an embodiment of the current invention, can provide for tuning the visible absorbance spectrum of the device to match scintillation output. The device can be fabricated from elements whose total x-ray absorbance in the device configuration is matched to the absorbance of biological tissue. Devices can be formatted so that multiple devices can be stacked in parallel planes for multiplicative current responses, with sets of anodes and sets of cathodes each connected in parallel.

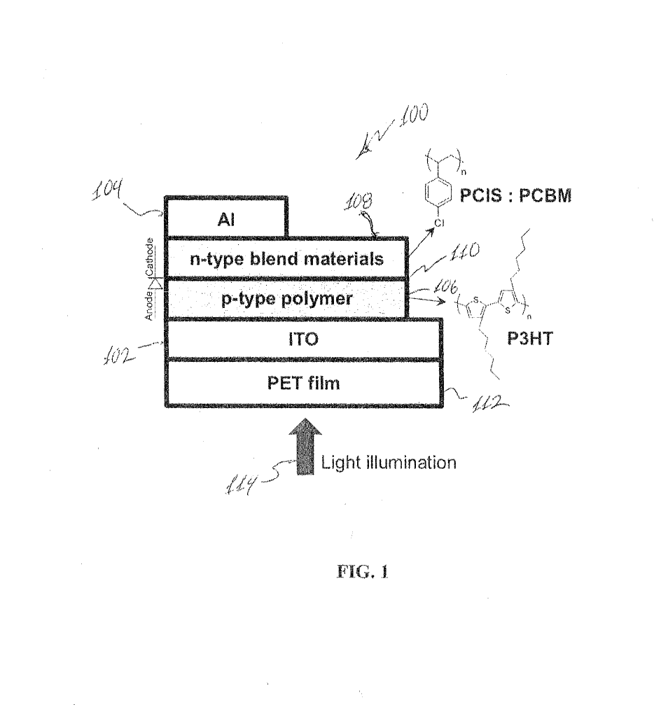

FIG. 1 is a schematic illustration of an x-ray detector 100 according to an embodiment of the current invention. The x-ray detector 100 includes a first electrode 102, a second electrode 104 spaced apart from the first electrode 102, an organic p-type semiconducting layer 106 disposed between the first and second electrodes (102, 104), and an organic n-type semiconducting layer 108 disposed between the first and second electrodes (102, 104) and in contact with the organic p-type semiconducting layer 106 to form a pn-junction layer 110 therebetween. At least one of the organic p-type semiconducting layer 106 or the organic n-type semiconducting layer 108 includes an x-ray absorbing material blended therein. Some embodiment of the current invention can include a substrate 112. The substrate is illustrated to be on the light incident side in FIG. 1. However, the general concepts of the current invention are not limited to this example. In addition, the broad concepts of the current invention are not limited to the particular materials shown in FIG. 1. The substrate can be a rigid or a flexible substrate, depending on the particular application.

The term “light” used in this specification is intended to have a broad meaning to include electromagnetic radiation in both visible and non-visible regions of the spectrum. In particular, the “light illumination” 114 indicated in FIG. 1 can be, or can include, x-rays.

In some embodiments, the x-ray absorbing material can include a material with an atomic element that has an atomic number greater than about 34. The atomic element, or elements, can be added to increase the average atomic number of the organic p-type semiconducting layer 106 and/or the organic n-type semiconducting layer 108 to improve x-ray absorption.

In some embodiments, the x-ray absorbing material can include metal particles in elemental form, for example, but not limited to tin, antimony, indium, tungsten, tantalum, bismuth, lead, etc., and/or alloys thereof. In some embodiments, the x-ray absorbing material can include, but is not limited to, powdered alloys containing, lead, bismuth, tin or alloys of tungsten etc., for example

In some embodiments, the x-ray absorbing material can include particles that include compounds of elements with atomic numbers greater than 30; for example including cesium, barium, iodine, cadmium, tin, antimony, cerium, indium, tungsten, tantalum, bismuth, lead, etc. For example, such compounds can include, but are not limited to, bismuth oxide, tungsten oxide, cerium oxide, tantalum oxide, barium sulfate, cesium iodide, lead sulfate, etc.

In some embodiments, particles that can be included as additives can include, but are not limited to, lead, bismuth, tellurium, and mercury. Further embodiments can include, but are not limited to, cadmium, indium, tin, and antimony.

Examples of compound semiconductors, which can be better than elemental materials for electronic, processing, and toxicity reasons according to some embodiments of the current invention, can include, but are not limited to, bismuth telluride, bismuth selenide, lead telluride, lead selenide, lead sulfide, mercury telluride, and mercury sulfide. According to some embodiments of the current invention, any compound semiconductor comprising the list of elements above could be used.

In some embodiments, the x-ray absorbing material can include particles with semiconductive properties that incorporate elements with atomic numbers of 30 or higher. Examples include lead iodide, bismuth telluride, cadmium telluride, cadmium zinc telluride, mercuric iodide, bismuth selenide, lead telluride, lead selenide, lead sulfide, mercury telluride, and mercury sulfide. More broadly, any compound semiconductor comprising the list of elements above could be used in some embodiments of the current invention.

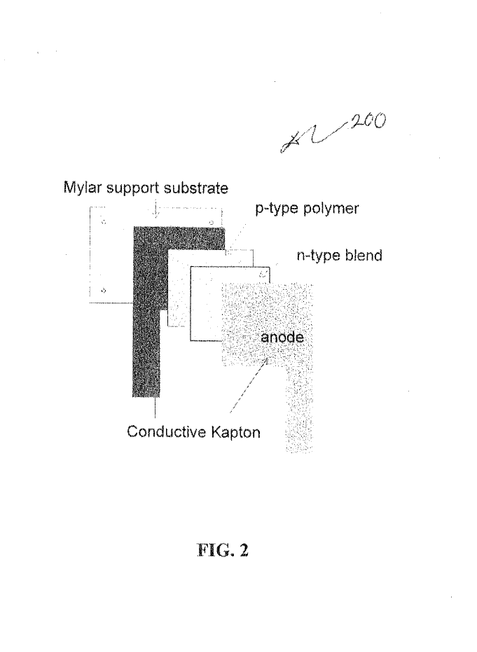

FIG. 2 is a schematic illustration of an x-ray detector 200 according to another embodiment of the current invention. It can be similar to the x-ray detector 100 illustrated in FIG. 1, except the electrodes (anode and cathode) can be structured in a “flag-like” shape to facilitate incorporation into stacked and/or arrayed configurations of a plurality of pn-junction components. The materials specified in FIG. 2 are non-limiting examples that can be useful in some embodiments.

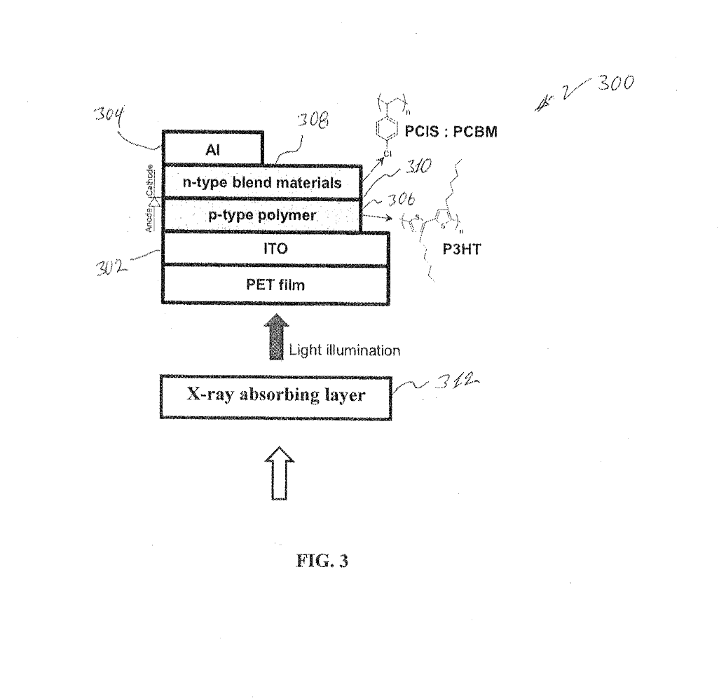

FIG. 3 is a schematic illustration of an x-ray detector 300 according to another embodiment of the current invention. The x-ray detector 300 includes a first electrode 302, a second electrode 304 spaced apart from the first electrode 302, an organic p-type semiconducting layer 306 disposed between the first and second electrodes (302, 304), an organic n-type semiconducting layer 308 disposed between the first and second electrodes (302, 304) and in contact with the organic p-type semiconducting layer 306 to form a pn-junction layer 310 therebetween, and an x-ray absorbing layer 312 disposed proximate at least one of the organic p-type semiconducting layer 306 or the organic n-type semiconducting layer 308 such that secondary electrons produced in the x-ray absorbing layer 312 in response to absorbed x-rays excite at least one of the organic p-type semiconducting layer 306 or the organic n-type semiconducting layer 308. FIG. 3 shows the x-ray absorbing layer 312 being on the opposing side of the first electrode 302 relative to the p-type semiconducting layer 306 and the n-type semiconducting layer 308. However, it can be formed closer to the p-type semiconducting layer 306 and/or n-type semiconducting layer 308 in other embodiments to enhance incidence of secondary electrons onto the p-type semiconducting layer 306 and/or n-type semiconducting layer 308.

In further embodiments, instead of a single x-ray absorbing layer 312, a multilayer structure can be used with multiple thin layers of x-ray absorbing materials interspersed between layers of organic p-type semiconducting layers and/or organic n-type semiconducting layers such that secondary electrons produced in the x-ray absorbing material in response to absorbed x-rays excite the following organic p-type semiconducting layer or the organic n-type semiconducting layer. In such a structure, the thickness of the organic p-type or n-type semiconducting layer can be thicker than the mean free path of secondary electrons generated in the preceding x-ray absorbing layer at the x-ray energies for which structure is designed.

In some embodiments, the x-ray absorbing layer can include a material that has an atomic element with an atomic number greater than about 30. In some embodiments, the x-ray absorbing layer can include metal particles. In some embodiments, the x-ray absorbing layer can include particles of organic and/or inorganic compounds of metal or otherwise heavy elements with atomic numbers greater than about 30. In some embodiments, the x-ray absorbing layer can include semiconducting particles.

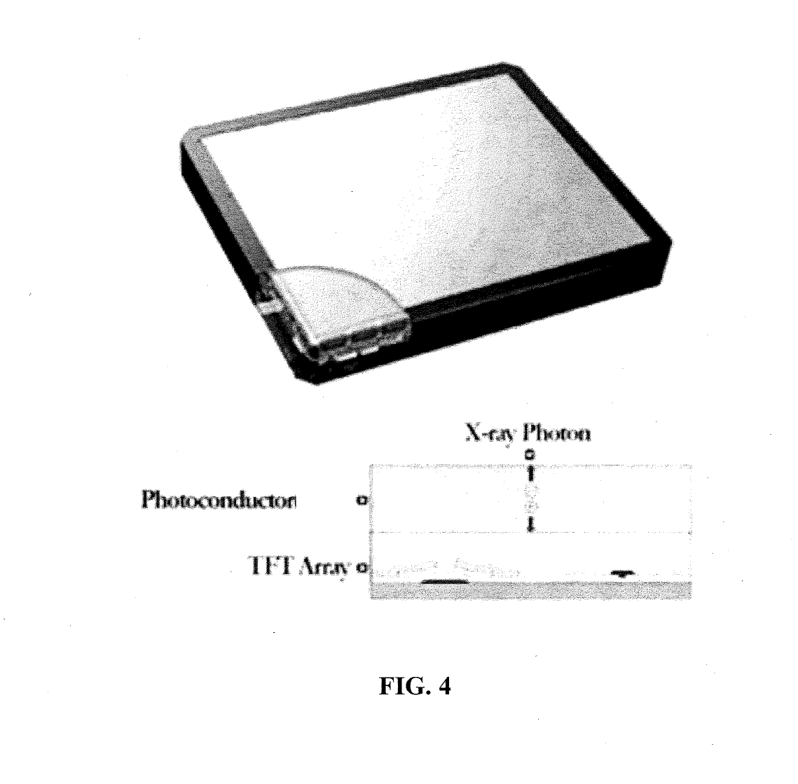

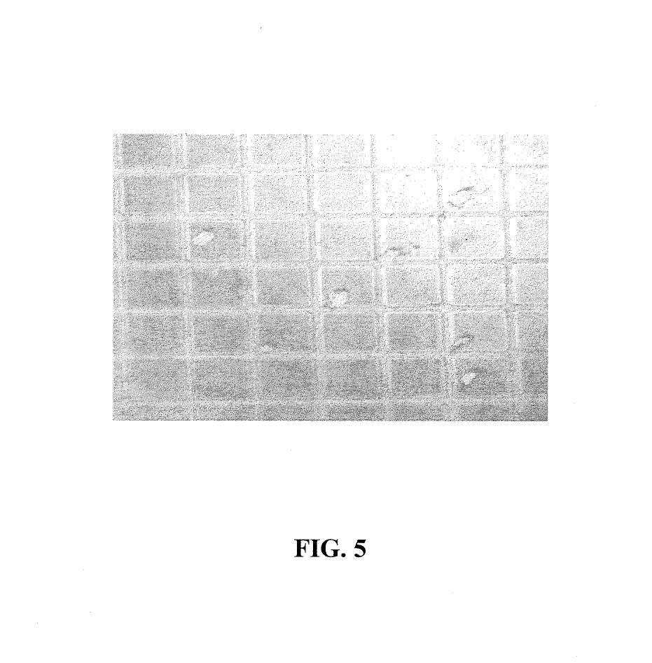

In further embodiments, a plurality of the elements illustrated in FIGS. 1, 2 and/or 3 can be combined together in one-dimensional, two-dimensional, vertically stacked and/or three-dimensional arrays. In some embodiments, such arrays can be configured into an x-ray imaging system. FIGS. 4 and 5 illustrate an example of a two-dimensional x-ray imaging system. In some embodiments, flexible substrates can be used to form flexible x-ray imaging systems such that the arrays can be arranged in non-planar configurations, such as, but not limited to, wrapping around an object to be imaged.

In another embodiment, a tissue-equivalent radiation detector can have a general structure similar to the devices of FIGS. 1-5. In this embodiment, the organic p-type semiconducting layer and the organic n-type semiconducting layer together have an average atomic number that is approximately 7.4 to substantially match an average atomic number of muscle tissue.

Some embodiments of the current invention can provide the following:
Use of blended electron-accepting small molecules in inert polymer matrix as the electron-transporting layer for a photodiode;
Use of plastic flag-shaped substrates for ability to stack active areas in parallel planes and connect analogous electrodes in parallel;
Photoactivity of an organic bilayer over >1 cm² area and on a flexible substrate;
Tunability of the organic bilayer so light absorbance matches scintillation output; and/or
Introduction of heavy element-containing compound semiconductor particles to increase x-ray sensitivity.

Some embodiments can include:
Hole carrying semiconductors—numerous compositions known in the art, including oligomers and thiophene polymers, and polymer blends
Electron carrying semiconductors—fullerenes, quinodimethanes, and tetracarboxylic diimides solution deposited or preferably blended with matrix materials to improve large area coatability and environmental stability; others are known in the art. They can be polymers or smaller molecules that have coating ability. Semiconductors can also be vapor deposited to a limited thickness.
Electrodes—ITO and aluminum are conventional; silver and carbon inks and glues for interconnection; carbon-plastic electrodes for low x-ray absorbance and large area. There are a variety of sizes and shapes that can be used, and different scintillation screens and backplanes.
Matrix polymers—polystyrenes, polyimides, poly(meth)acrylates can be used. Many other inert or electronically compatible polymers are known.

Some applications can include, but are not limited to, the following:

### 1) Tissue Equivalent Radiation Dosimetry

i) Inexpensive self-reading dosimeters for personnel radiation monitoring

ii) Dosimeters for monitoring patients during radiation therapy, and prolonged x-ray fluoroscopies

iii) 2 and 3 dimensional dosimeter arrays for radiation therapy quality control

iv) X-ray invisible detectors for automatic exposure controllers in radiography

### 2) Inexpensive One and Two Dimensional Diode Arrays for Medical, Dental, Veterinary, Industrial and Security X-Ray Imaging

i) Versions designed for use with a scintillator screen and tuned to the optical emissions of that screen

ii) Versions designed for direct x-ray absorption without a scintillator screen and incorporating heavy metals.

iii) Versions where the detector is flexible to curve around an imaged object

iv) Ultra high-resolution arrays for use in mammography

v) Versions with dynamic readout at high frame rates for fluoroscopy and CT scanning

Further additional concepts and embodiments of the current invention will be described by way of the following examples. However, the broad concepts of the current invention are not limited to these particular examples.

### EXAMPLES

In the following examples, we demonstrate a solution processable, organic p-n junction vertical photodiode, fabricated and operated under ambient conditions, with low dark current using P3HT and PCBM:PClS blends as a p- and n-type photoactive layer, respectively. We investigated the photosensitivity with various film thicknesses and different sizes of aluminium (Al) top electrodes. We demonstrated continuous photoresponse of the photodiodes under intermittent light illumination using xenon, halogen and UV lamps.

### Material and Methods

Bilayer organic films were prepared by solution processing using P3HT and PClS:PCBM blends under ambient conditions. Diodes were fabricated on flexible and transparent polyester (PET) films with indium tin oxide (ITO) as the anode material. We used ITO-PET substrates without further modifications such as oxygen plasma treatment or interfacial charge-blocking layer deposition. P3HT (4002-EE, Rieke Metals) was deposited from various concentrations of the solution (10˜15 mg/mL) in CB at spinning speeds of 500 RPM. Upper films of PCBM (Nano-C) and PCIS (Sigma-Aldrich, average molecular weight 75,000) (9:1 weight ratio) were deposited from various concentrations of the solutions (10˜15 mg/mL) in DCM at spinning speeds of 500 RPM on top of the P3HT layers. Organic semiconductor solutions were filtered through 0.45 μm poly(tetrafluoroethylene) (PTFE) filters prior to deposition. Aluminium top electrodes with a thickness of approximately 100 nm and active area of 0.062 to 6.2 mm² were thermally evaporated through a shadow mask. All samples were exposed to various lights through the PET-ITO side in air. Current density-voltage (J-V) characteristics of the devices were measured with an Agilent 4155C semiconductor parameter analyzer, under dark and various light illuminations (Xenon lamp with a light intensity of 112˜291 mW/cm², Halogen lamp with a light intensity of 0.013˜1.51 mW/cm², and UV lamp (λ=365 nm) with a light intensity of 0.35 mW/cm²). The device used in the internal photoconversion efficiency (IPCE) experiment was illuminated through its ITO side with a 100 W Xe lamp (PhotoMax) coupled to an f/0.39 Oriel Cornerstone monochromator. Incident irradiances were measured using an optometer (Graesby Optronics S370 with a United Detector Technology silicon detector), and photocurrents were measured using an electrometer (Keithley 617).

### Results and Discussion

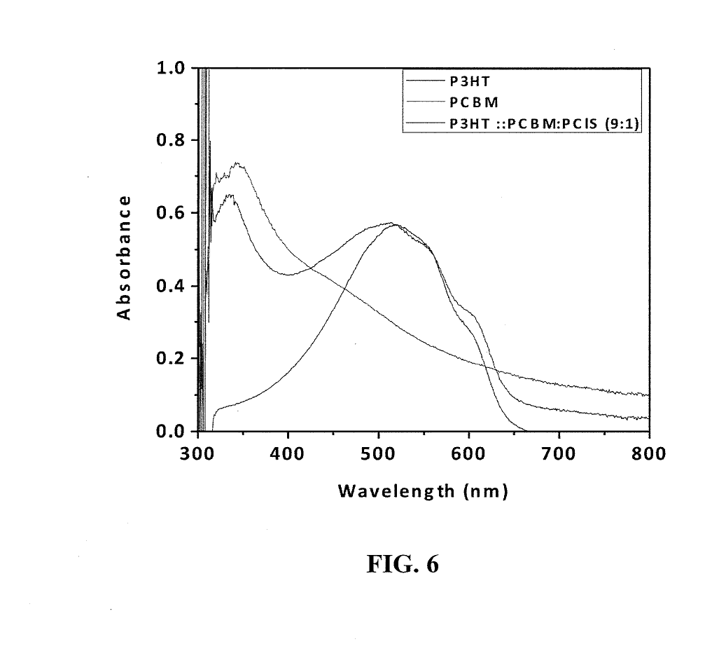

FIG. 6 shows the UV-visible absorption spectra of P3HT, PCBM, and P3HT:PCBM (Bilayer) film on PET-ITO. The absorption maxima for P3HT were in the 400-600 nm region and for PCBM at 325 nm. The P3HT:PCBM (bilayer) film exhibited broad absorption in the UV-vis region, which will promote efficient photon absorption and exciton generation.

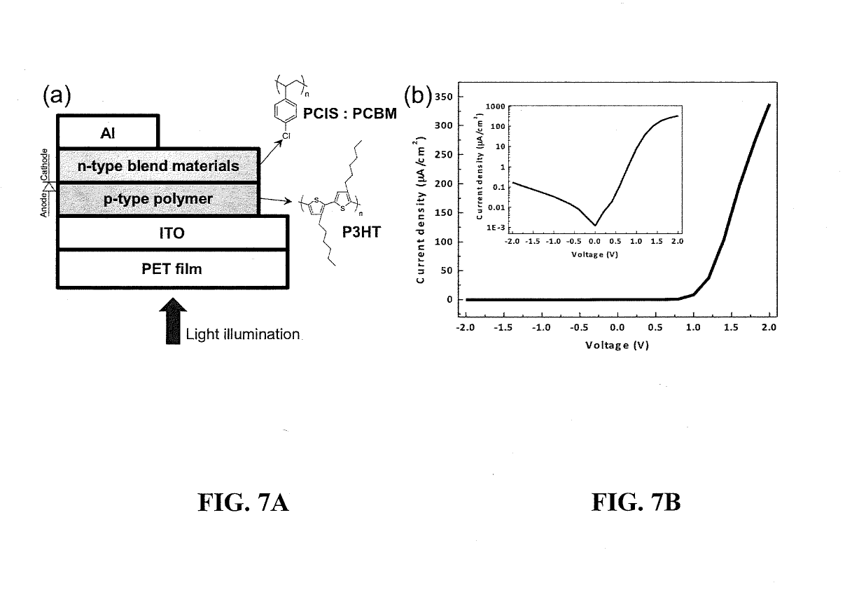

FIG. 7A shows the structure of the photodiode used in this example. The PCBM-PClS blend was first characterized as a top-gated transistor on plastic. Interdigitated source-drain electrodes were prepared from PEDOT-PSS on Mylar polyester. The blend solution was spincoated from chlorobenzene. Cytop fluorinated polymer was then spincoated to serve as the gate dielectric, with specific capacitance of 1-2 nF/cm². PEDOT-PSS gate electrodes were then formed. The field-effect mobility measured under vacuum was 0.003 cm²/Vs, comparable to that of neat PCBM and PCBM-PBrS blend devices prepared under similar conditions, and sufficient for charge injection into vertical thin-film devices. The mobility of the PClS blend was lower when spincoated on silicon-SiO₂ substrates because of poorer wettability of the coating solution on that substrate.

Typical current density-voltage (J-V) characteristics of the bilayer diode device that consisted of ITO/P3HT/PCBM:PClS/Al (0.062 mm²) under dark condition are shown in FIG. 7B. In the dark, the device showed a good rectification ratio (2.0×10³) from −2.0 to +2.0 V (FIG. 7B inset), with turn-on voltage of 1.1 V, and low reverse bias leakage current density. At a forward bias voltage of +2.0 V, a current density of 340 μA/cm² was observed.

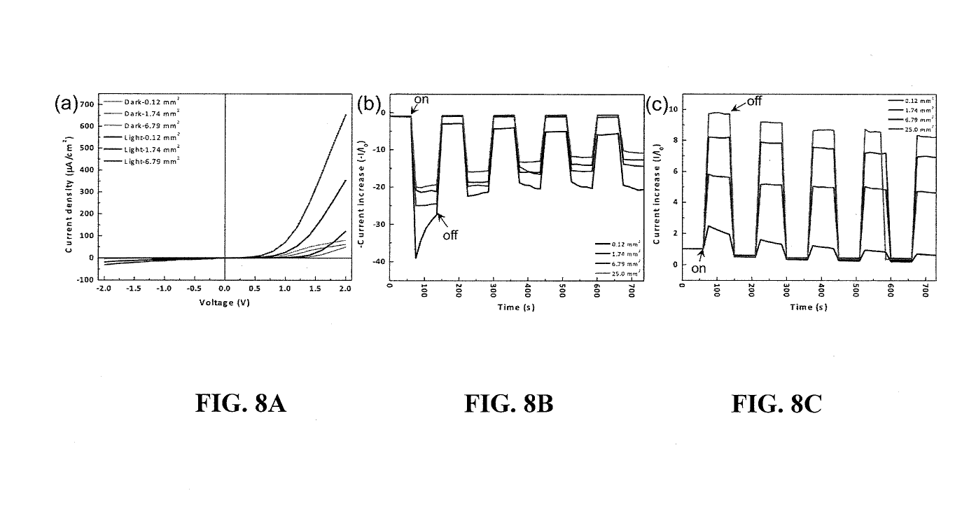

We fabricated diodes with different Al (top electrode) areas (0.12 to 6.79 mm²) to examine the dependence of photoresponse on the cathode size (FIG. 8). The samples were illuminated by using a Xenon lamp with a light intensity of 130 mW/cm². Only a minor area dependence of currents was found in the dark and irradiated samples in the reverse bias regime (−2 V), where the photodiode operated as a p-n junction or heterojunction-limited device. At +2V, where the device would operate as a simple photoconductor, larger Al area led to stronger photoresponse, suggesting that the large area increased the probability of a particularly active photoconducting path. In general, the reverse bias regime was more photoresponsive (giving larger relative photoinduced current changes), as expected considering the nonlinear dependence of resistance on the junction barrier height.

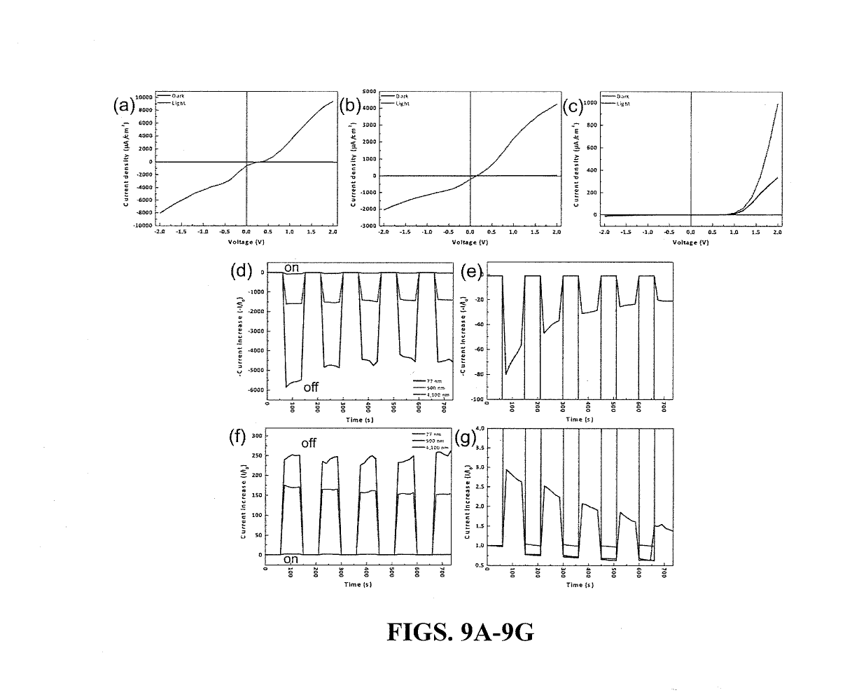

Different concentrations of spincoating solutions were employed in order to obtain various thicknesses of films and investigate the photoresponses (FIG. 9). The thicknesses of the films were measured using surface profilometry (Veeco Dektak). At both bias voltages of +2.0 and −2.0 V and for all three thicknesses, photoenhanced conductances were observed. Photoresponse was greatest for thinner films and −2.0 V (reverse bias). The current of the photodiode device with a 77 nm thick active layer increased 6000 times under light irradiation (Xenon lamp with a light intensity of 130 mW/cm²) at reverse bias voltage. The current density of this same device was 6 mA/cm² at −1.49 V when illuminated with light intensity of 130 mW/cm², higher than a previously reported photodiode with layer sequence ITO/PEDOT:PSS/P3HT:PCBM, for which a current density of 1.28 mA/cm² at −1.49 V when illuminated with light intensity of 100 mW/cm² had been observed.[39] The response was observed to be fast and highly reversible. The smaller responses of the thicker devices could have been because of generally higher series resistance and/or because of greater recombination probabilities.

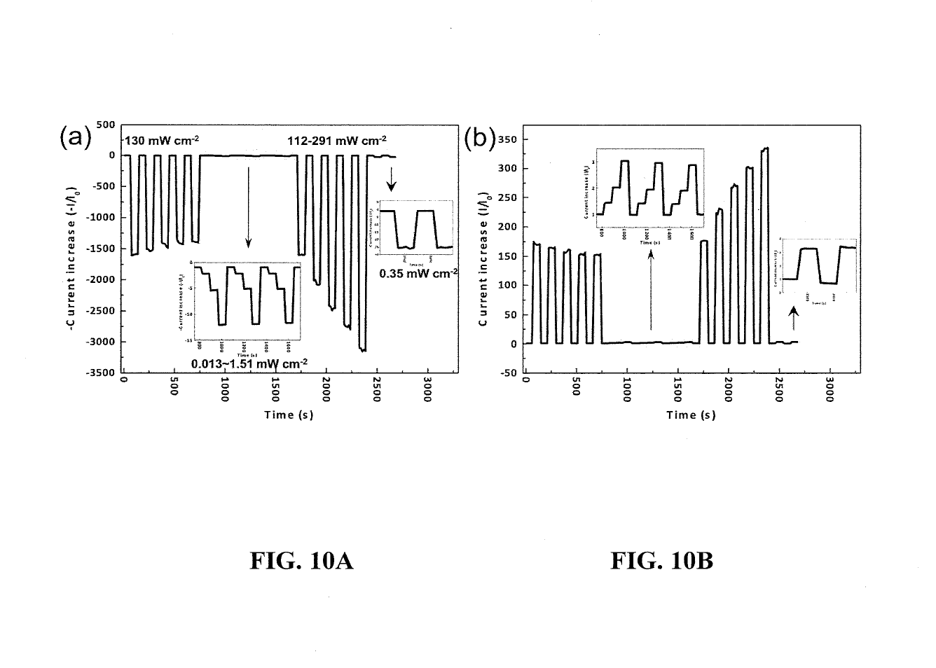

We demonstrated repeatable and monotonically increasing photoresponse as a function of intensity using intervals of exposure to a xenon lamp with a light intensity of 112˜291 mW/cm², halogen lamp with a light intensity of 0.013˜1.51 mW/cm², and UV lamp (λ=365 nm) with a light intensity of 0.35 mW/cm² (FIG. 10A). The devices showed reversible and stable photoresponse without any clear degradation at ±2.0 V bias voltage under, alternately very strong (Xenon lamp) and very weak (Halogen and UV lamp) illumination for 50 min (FIG. 10B). Under the UV illumination (λ=365 nm) of 0.35 mW/cm², the device showed 25 times increased photocurrent. In addition, when the intensity of the irradiated light was changed (0.013˜291 mW/cm²), a sublinear dependence of the photocurrent on the light intensity was observed.

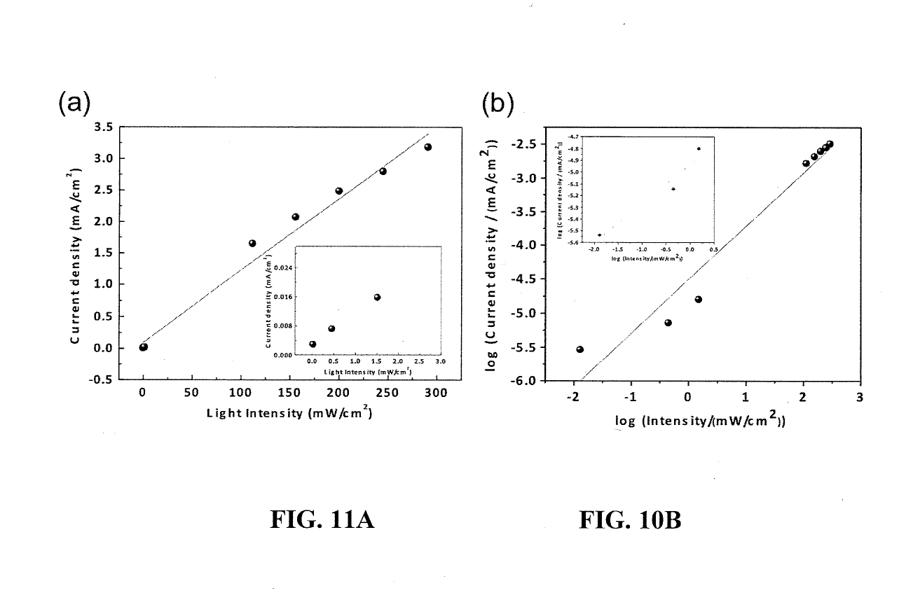

The photocurrent dependence on the light intensity is expressed by the power law Jₚₕ=BP^{α}, where, Jₚₕ is the photocurrent, B is a constant, α is an exponent and P is the intensity of the light.[40] For the data in FIG. 11B we find α=0.79, corresponding to current density∝(intensity)0.79. It has been stated that for monomolecular recombination, α=1, and for bimolecular recombination, α=0.5 [40]. Recombination of charge and space charge limitation both play an important role in reduction of photocurrent; the importance of each is indicated by the value of α. In the case of space charge limited currents, the relationship of current density vs light intensity is sublinear, and the a value depends upon the distribution of traps within the forbidden energy gap. A previous report discussed the origin of the light intensity dependence on current for organic polymer/fullerene solar cells and showed that the sublinear photocurrent dependence on the light intensity is mainly due to space charge and not due to the influence of bimolecular recombination. Similarly, we observed a sublinear photocurrent dependence on the light intensity for the system ITO/P3HT/PCBM:PClS/Al wherein the deviation from the linearity could be explained due to charge and space charge recombination (FIG. 11A and 11B). [41, 42]

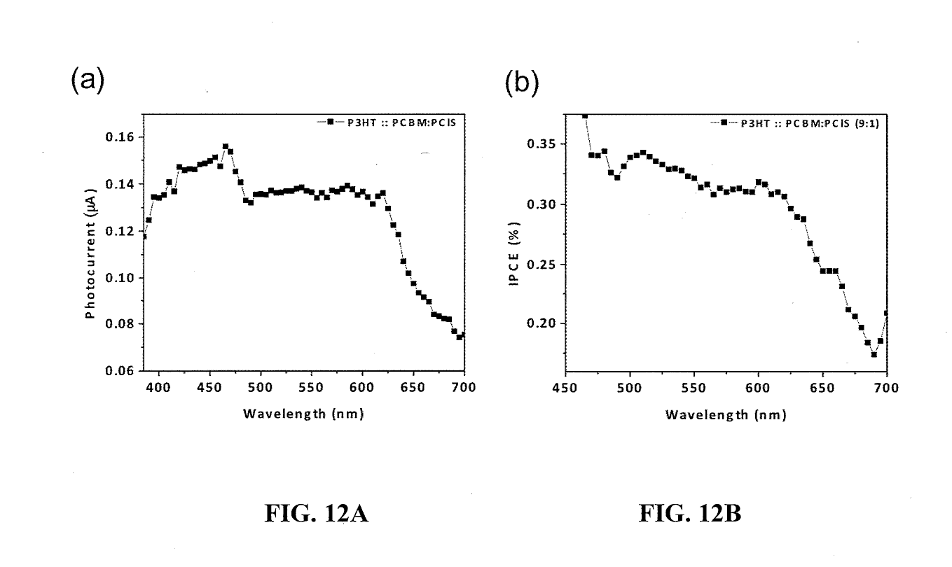

IPCE spectra for the device P3HT/PCBM:PClS (bilayer) are shown in FIG. 12. The IPCE maximum of 0.35% was 510 nm, very close to the UV absorbance maximum of 518 nm. The IPCE value is within an order of magnitude of the efficiency (2.64%) reported for a bilayer P3HT/PCBM system. [32] That latter system used a rigid substrate and a PEDOT interlayer, was made by inert-atmosphere deposition and annealing to control material order and mixing, and included a carefully optimized compositional gradient and bulk heterojunction morphology, which would give a much higher internal interfacial area.

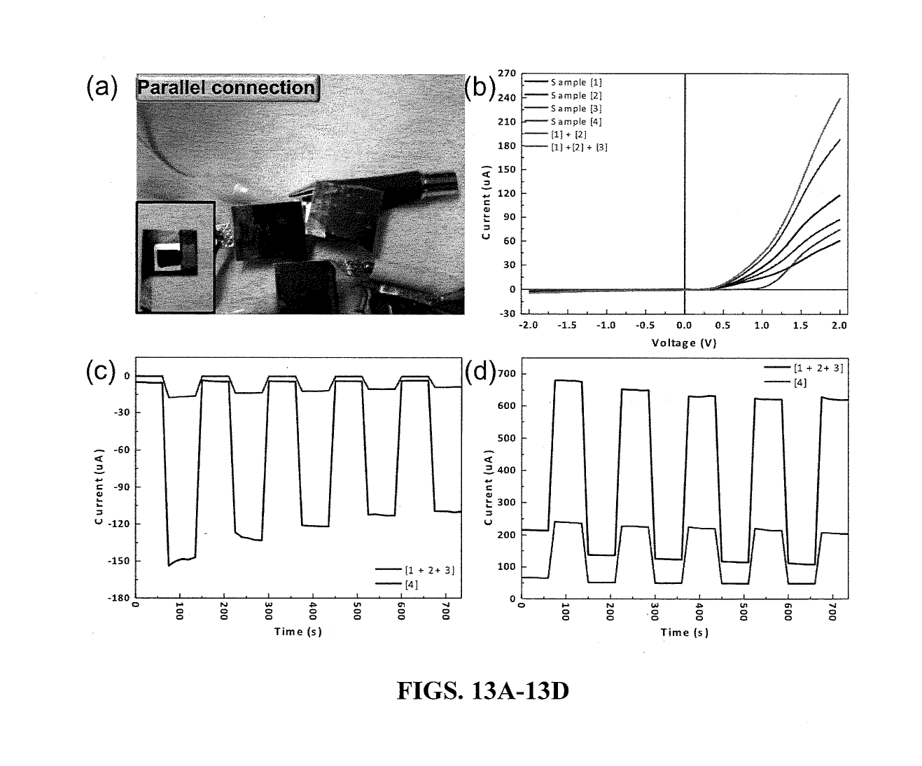

To test the additivity of multiple photodiode responses, to rule out parasitic series resistances from the interconnections and realize larger exposure areas from smaller fabricated film areas, three identical devices were connected in parallel (FIG. 13). In the dark, each unit device showed forward bias current of 60 to 80 μA. The current of the multiple diode devices connected in parallel was found to be similar to the sum of the individual currents of each unit device. In addition, under light illumination, the photoresponse of the multiple devices in parallel resulted in amplified current corresponding to the sum of the responses of each unit device at reverse bias.

### CONCLUSION

We describe the fabrication of solution processable organic p-n junction bilayer vertical photodiode devices according to an embodiment of the current invention using an orthogonal solvent combination of CB and DCM for P3HT and PCBM:PClS blends respectively. In the dark, the diodes showed a good rectification ratio (2.0×10³) at ±2.0 V with a forward bias current density as high as 340 μA/cm² at 2.0 V. Photodiodes with different thicknesses of films were constructed and the thinner active layer resulted in larger photocurrent and photoresponse in comparison to thicker films. Under repeated illumination by strong and weak light sources, the diodes showed reversible and stable photoresponses, nearly linear in light intensity, without any clear degradation at ±2.0 V bias voltages.

### REFERENCES

[1] N. Tessler, N. T. Harrison, R. H. Friend, Adv. Mater. 10 (1998) 64-68.

[2] M. J. Park, J. Lee, J. Kwak, I. H. Jung, J. H. Park, H. Kong, C. Lee, D. H. Hwang, H. K. Shim, Macromolecules 42 (2009) 5551-5557.

[3] M. J. Park, J. Kwak, J. Lee, I. H. Jung, H. Kong, C. Lee, D. H. Hwang, H. K. Shim, Macromolecules 43 (2010) 1379-1386.

[4] H. Kong, Y. K. Jung, N. S. Cho, I. N. Kang, J. H. Park, S. Cho, H. K. Shim Chem. Mater. 21 (2009) 2650-2660.

[5] H. Kong, S. Cho, D. H. Lee, N. S. Cho, M. J. Park, I. H. Jung, J. H. Park, C. E. Park, H. K. Shim, J. Polym. Sci. Pol. Chem. 49 (2011) 2886-2898.

[6] J. H. Park, D. H. Lee, H. Kong, M. J. Park, I. H. Jung, C. E. Park, H. K. Shim, Org. Electron. 11 (2010) 820-830.

[7] B. S. Ong, Y. L. Wu, P. Liu, S. Gardner, J. Am. Chem. Soc. 126 (2004) 3378-3379.

[8] H. L. Pan, Y. N. Li, Y. L. Wu, P. Liu, B. S. Ong, S. P. Zhu, G. Xu, J. Am. Chem. Soc. 129 (2007) 4112-4113.

[9] J. Li, F. Qin, C. M. Li, Q. L. Bao, M. B. Chan-Park, W. Zhang, J. G. Qin, B. S. Ong, Chem. Mater. 20 (2008) 2057-2059.

[10] H. Bronstein, D. S. Leem, R. Hamilton, P. Woebkenberg, S. King, W. M. Zhang, R. S. Ashraf, M. Heeney, T. D. Anthopoulos, J. de Mello, I. McCulloch, Macromolecules 44 (2011) 6649-6652.

[11] H. Kong, J. S. Moon, N. S. Cho, I. H. Jung, M. J. Park, J. H. Park, S. Cho, H. K. Shim, Appl. Phys. Lett. 95 (2009) 173301.

[12] D. S. Chung, H. Kong, W. M. Yun, H. Cha, H. K. Shim, Y. H. Kim, C. E. Park, Org. Electron. 11 (2010) 899-904.

[13] I. H. Jung, J. Yu, E. Jeong, J. Kim, S. Kwon, H. Kong, K. Lee, H. Y. Woo, H. K. Shim, Chem-Eur. J. 16 (2010) 3743-3752.

[14] N. C. Cates, R. Gysel, Z. Beiley, C. E. Miller, M. F. Toney, M. Heeney, I. McCulloch, M. D. McGehee, Nano Lett. 9 (2009) 4153-4157.

[15] Z. Y. Chen, M. J. Lee, R. S. Ashraf, Y. Gu, S. Albert-Seifried, M. M. Nielsen, B. Schroeder, T. D. Anthopoulos, M. Heeney, I. McCulloch, H. Sirringhaus, Adv. Mater. 24 (2012) 647-652.

[16] T. Agostinelli, M. Campoy-Quiles, J. C. Blakesley, R. Speller, D. D. C. Bradley, J. Nelson, Appl. Phys. Lett. 93 (2008) 203305.

[17] H. F. Zhu, T. Li, Y. J. Zhang, H. L. Dong, J. S. D. Song, H. P. Zhao, Z. M. Wei, W. Xu, W. P. Hu, Z. S. Bo, Adv. Mater. 22 (2010) 1645-1648.

[18] D. Baierl, B. Fabel, P. Lugli, G. Scarpa, Org. Electron. 12 (2011) 1669-1673.

[19] K. Jain, M. Klosner, M. Zemel, S. Raghunandan, P. IEEE 93 (2005) 1500-1510.

[20] F. A. Boroumand, M. Zhu, A. B. Dalton, J. L. Keddie, P. J. Sellin, J. J. Gutierrez, Appl. Phys. Lett. 91 (2007) 033509.

[21] Y. Zhou, L. Wang, J. Wang, J. Pei, Y. Cao, Adv. Mater. 20 (2008) 3745-3749.

[22] H. G. Li, G. Wu, H. Z. Chen, M. Wang, Curr. Appl. Phys. 11 (2011) 750-754.

[23] J. Cabanillas-Gonzalez, O. Pena-Rodriguez, I. S. Lopez, M. Schmidt, M. I. Alonso, A. R. Goni, M. Campoy-Quiles, Appl. Phys. Lett. 99 (2011) 103305.

[24] M. Binda, D. Natali, M. Sampietro, T. Agostinelli, L. Beverina, Nucl. Instrum. Meth. A, 624 (2010) 443-448.

[25] F. Yan, H. H. Liu, W. L. Li, B. Chu, Z. S. Su, G. Zhang, Y. R. Chen, J. Z. Zhu, D. F. Yang, J. B. Wang, Appl. Phys. Lett. 95 (2009) 253308.

[26] I. H. Campbell, B. K. Crone, Appl. Phys. Lett. 95 (2009) 263302.

[27] H. Tanaka, T. Yasuda, K. Fujita, T. Tsutsui, Adv. Mater. 18 (2006) 2230-2233.

[28] M. S. Arnold, J. D. Zimmerman, C. K. Renshaw, X. Xu, R. R. Lunt, C. M. Austin, S. R. Forrest, Nano Lett. 9 (2009) 3354-3358.

[29] P. E. Keivanidis, N. C. Greenham, H. Sirringhaus, R. H. Friend, J. C. Blakesley, R. Speller, M. Campoy-Quiles, T. Agostinelli, D. D. C. Bradley, J. Nelson, Appl. Phys. Lett. 92 (2008) 023304.

[30] M. Ramuz, L. Burgi, C. Winnewisser, P. Seitz, Org. Electron. 9 (2008) 369-376.

[31] M. Al-Ibrahim, H.-K. Roth, U. Zhokhavets, G. Gobsch, S. Sensfuss, Sol. Energy Mater. Sol. Cells 85 (2005) 13-20.

[32] D. H. Wang, D.-G Choi, O. O. Park, J. H. Park, J. Mater. Chem. 20 (2010) 4910-4915.

[33] S. B. Kirschner, N. P. Smith, K. A. Wepasnick, H. E. Katz, B. J. Kirby, J. A. Borchers, D. H. Reich, J. Mater. Chem. 22 (2012) 4364-4370.

[34] S. Kola, N. J. Tremblay, M. L. Yeh, H. E. Katz, S. B. Kirschner, D. H. Reich, ACS Macro Lett. 1 (2012) 136-140.

[35] V. S. Gevaerts, L. J. A. Koster, M. M. Wienk, R. A. J. Janssen, ACS Appl. Mater. Inter. 3 (2011) 3252-3255.

[36] J. S. Moon, C. J. Takacs, Y. M. Sun, A. J. Heeger Nano Lett. 11 (2011) 1036-1039.

[37] A. Loiudice, A. Rizzo, G. Latini, C. Nobile, M. de Giorgi, G. Gigli 100 (2012) 147-152.

[38] L. S. Roman, Photovoltaic Devices Based on Polythiophene/C₆₀, in: S. S. Sun, N. S. Sariciftci, Organic Photovoltaics: Mechanisms, Materials, and Devices, Taylor & Francis Group, Florida, 2005, pp 367-386.

[39] Chirvase, D.; Chiguvare, Z.; Knipper, M.; Parisi, J.; Dyakonov, V.; Hummelen, J. C. Synth. Met. 138 (2003) 299-304.

[40] Mihailetchi, V. D.; Wildeman, J.; Blom, P. W. M. Phys. Rev. Lett. 94 (2005) 126602.

[41] Goodman, A. M.; Rose, A. J. Appl. Phys, 42 (1971) 2823.

[42] Koster, L. J. A.; Mihailetchi, V. D.; Xie, H.; Blom, P. W. M. Appl. Phys. Lett. 87 (2005) 203502.

The embodiments illustrated and discussed in this specification are intended only to teach those skilled in the art how to make and use the invention. In describing embodiments of the invention, specific terminology is employed for the sake of clarity. However, the invention is not intended to be limited to the specific terminology so selected. The above-described embodiments of the invention may be modified or varied, without departing from the invention, as appreciated by those skilled in the art in light of the above teachings It is therefore to be understood that, within the scope of the claims and their equivalents, the invention may be practiced otherwise than as specifically described.

We claim:

1. An x-ray detector, comprising:
a first electrode;
a second electrode spaced apart from said first electrode;
an organic p-type semiconducting layer disposed between said first and second electrodes; and
an organic n-type semiconducting layer disposed between said first and second electrodes and in contact with said organic p-type semiconducting layer to form a pn-junction layer therebetween,
wherein at least one of said organic p-type semiconducting layer or said organic n-type semiconducting layer comprises an x-ray absorbing material blended therein.

2. An x-ray detector according to claim 1, wherein said x-ray absorbing material comprises an atomic element having an atomic number greater than about 34 that increases an average atomic number of at least one of said organic p-type semiconducting layer or said organic n-type semiconducting layer to improve x-ray absorption.

3. An x-ray detector according to claim 1, wherein said x-ray absorbing material comprises metal particles in elemental form.

4. An x-ray detector according to claim 3, wherein said metal particles comprise at least one of tin, antimony, indium, tungsten, tantalum, bismuth, lead, or any alloys thereof.

5. An x-ray detector according to claim 1, wherein said x-ray absorbing material comprises particles comprising compounds of elements with atomic numbers greater than 30 to enhance x-ray absorption.

6. An x-ray detector according to claim 5, wherein said compounds of elements with atomic numbers greater than 30 comprise at least one of cesium, barium, iodine, cadmium, tin, antimony, cerium, indium, tungsten, tantalum, bismuth, lead, or any combination thereof.

7. An x-ray detector according to claim 5, wherein said compounds of elements with atomic numbers greater than 30 comprise at least one of bismuth oxide, tungsten oxide, cerium oxide, tantalum oxide, barium sulfate, cesium iodide, lead sulfate, bismuth telluride, bismuth selenide, lead telluride, lead selenide, lead sulfide, mercury telluride, mercury sulfide, or any combination thereof.

8. An x-ray detector according to claim 1, wherein said x-ray absorbing material comprises semiconducting particles comprising an atomic element with an atomic number of at least 30 to enhance x-ray absorption.

9. An x-ray detector according to claim 8, wherein said semiconducting particles comprise at least one of lead iodide, bismuth telluride, cadmium telluride, cadmium zinc telluride, mercuric iodide, bismuth selenide, lead telluride, lead selenide, lead sulfide, mercury telluride, mercury sulfide, or any combination thereof.

10. An x-ray detector, comprising:
a first electrode;
a second electrode spaced apart from said first electrode;
an organic p-type semiconducting layer disposed between said first and second electrodes;
an organic n-type semiconducting layer disposed between said first and second electrodes and in contact with said organic p-type semiconducting layer to form a pn-junction layer therebetween; and
an x-ray absorbing layer disposed proximate at least one of said organic p-type semiconducting layer or said organic n-type semiconducting layer such that secondary electrons produced in said x-ray absorbing layer in response to absorbed x-rays excite at least one of said organic p-type semiconducting layer or said organic n-type semiconducting layer.

11. An x-ray detector according to claim 10, wherein said x-ray absorbing layer comprises a material comprising an atomic element having an atomic number greater than about 30 to enhance x-ray absorption.

12. An x-ray detector according to claim 11, wherein said material of said x-ray absorbing layer comprises metal particles.

13. An x-ray detector according to claim 11, wherein said material of said x-ray absorbing layer comprises a compound comprising said atomic element.

14. An x-ray detector according to claim 11, wherein said material of said x-ray absorbing layer comprises semiconducting particles.

15. An x-ray imaging system, comprising an array of x-ray detector elements, wherein at least one x-ray detector element of said array of x-ray detector elements comprises:
a first electrode;
a second electrode spaced apart from said first electrode;
an organic p-type semiconducting layer disposed between said first and second electrodes; and
an organic n-type semiconducting layer disposed between said first and second electrodes and in contact with said organic p-type semiconducting layer to form a pn-junction layer therebetween,
wherein at least one of said organic p-type semiconducting layer or said organic n-type semiconducting layer comprises an x-ray absorbing material blended therein.

16. An x-ray imaging system according to claim 15, wherein said x-ray absorbing material comprises an atomic element having an atomic number greater than about 34 that increases an average atomic number of at least one of said organic p-type semiconducting layer or said organic n-type semiconducting layer to improve x-ray absorption.

17. An x-ray imaging system according to claim 15, wherein said x-ray absorbing material comprises metal particles in elemental form.

18. An x-ray imaging system according to claim 17, wherein said metal particles comprise at least one of tin, antimony, indium, tungsten, tantalum, bismuth, lead, or any alloys thereof.

19. An x-ray imaging system according to claim 15, wherein said x-ray absorbing material comprises particles comprising compounds of elements with atomic numbers greater than 30 to enhance x-ray absorption.

20. An x-ray imaging system according to claim 19, wherein said compounds of elements with atomic numbers greater than 30 comprise at least one of cesium, barium, iodine, cadmium, tin, antimony, cerium, indium, tungsten, tantalum, bismuth, lead, or any combination thereof.

21. An x-ray imaging system according to claim 19, wherein said compounds of elements with atomic numbers greater than 30 comprise at least one of bismuth oxide, tungsten oxide, cerium oxide, tantalum oxide, barium sulfate, cesium iodide, lead sulfate, bismuth telluride, bismuth selenide, lead telluride, lead selenide, lead sulfide, mercury telluride, mercury sulfide, or any combination thereof.

22. An x-ray imaging system according to claim 15, wherein said x-ray absorbing material comprises semiconducting particles comprising an atomic element with an atomic number of at least 30 to enhance x-ray absorption.

23. An x-ray imaging system according to claim 22, wherein said semiconducting particles comprise at least one of lead iodide, bismuth telluride, cadmium telluride, cadmium zinc telluride, mercuric iodide, bismuth selenide, lead telluride, lead selenide, lead sulfide, mercury telluride, mercury sulfide, or any combination thereof.

24. An x-ray imaging system, comprising an array of x-ray detector elements, wherein at least one x-ray detector element of said array of x-ray detector elements comprises:
a first electrode;
a second electrode spaced apart from said first electrode;
an organic p-type semiconducting layer disposed between said first and second electrodes;
an organic n-type semiconducting layer disposed between said first and second electrodes and in contact with said organic p-type semiconducting layer to form a pn-junction layer therebetween; and
an x-ray absorbing layer disposed proximate at least one of said organic p-type semiconducting layer or said organic n-type semiconducting layer such that secondary electrons produced in said x-ray absorbing layer in response to absorbed x-rays excite at least one of said organic p-type semiconducting layer or said organic n-type semiconducting layer.

25. An x-ray imaging system according to claim 24, wherein said x-ray absorbing layer comprises a material comprising an atomic element having an atomic number greater than about 30 to enhance x-ray absorption.

26. An x-ray imaging system according to claim 25, wherein said material of said x-ray absorbing layer comprises metal particles.

27. An x-ray imaging system according to claim 25, wherein said material of said x-ray absorbing layer comprises a compound comprising said atomic element.

28. An x-ray imaging system according to claim 25, wherein said material of said x-ray absorbing layer comprises semiconducting particles.

29. A tissue-equivalent radiation detector, comprising:
a first electrode;
a second electrode spaced apart from said first electrode;
an organic p-type semiconducting layer disposed between said first and second electrodes; and
an organic n-type semiconducting layer disposed between said first and second electrodes and in contact with said organic p-type semiconducting layer to form a pn-junction layer therebetween,
wherein said organic p-type semiconducting layer and said organic n-type semiconducting layer together have an average atomic number that is approximately 7.4 to substantially match an average atomic number of muscle tissue.
